(19) United States
(12) Patent Application Publication
(10) Pub. No.: US 2010/0288552 A1
(43) Pub. Date: Nov. 18, 2010

(54) System and Method for Utilizing Plastic Conductive Gaskets

(75) Inventors: Albert Pedoeem, West Orange, NJ (US); Mahesh Mistry, Parsippany, NJ (US)

Correspondence Address: BAKER BOTTS L.L.P., 2001 ROSS AVENUE, SUITE 600, DALLAS, TX, 75201-2980, US

(73) Assignee: Fujitsu Network Communications, Inc., Richardson, TX (US)

(21) Appl. No.: 12/464,432

(22) Filed: May 12, 2009

(51) Int. Cl. H05K 9/00

(52) U.S. Cl. 174/378

(57) ABSTRACT

A system and method for shielding electromagnetic radiation includes an apparatus for shielding electromagnetic radiation. The apparatus includes a conductive surface comprised of electrically-conductive plastic. The apparatus further includes a flexible element comprised of electrically-conductive plastic extending from the conductive surface. The element is operable to contact an adjacent surface abutting the flexible element and form a conductive connection with the adjacent surface. When assembled with other components in a housing, the electrically-conductive surface and the flexible element may form a portion of a Faraday shield.

### TECHNICAL FIELD OF THE INVENTION

This invention relates generally to electrically-conductive plastic, and more particularly to a method and system for shielding electrical components by utilizing electrically-conductive plastic panels.

### BACKGROUND OF THE INVENTION

In certain electrical component systems, electrical components generate radiated electrical emissions that may interfere with other electrical components. As part of an electrical assembly, a Faraday cage may shield components housed inside the shield from externally-generated electromagnetic radiation, and thus substantially reduce or eliminate electromagnetic interference. Similarly, a Faraday cage may shield electrical components external to the Faraday cage from electromagnetic interference generated from within the Faraday cage. When all components in a cage form an electrical connection, a Faraday cage may be formed.

### SUMMARY OF THE INVENTION

The present invention provides a method and system for shielding electrical components from electromagnetic interference by utilizing electrically-conductive plastic that substantially reduces or eliminates at least some of the disadvantages and problems associated with previous methods and systems for shielding electrical components.

In accordance with one embodiment of the present invention, a system for shielding electrical components includes an apparatus for shielding electromagnetic radiation. The apparatus includes a conductive surface comprised of electrically-conductive plastic. The apparatus further includes a flexible element comprised of electrically-conductive plastic extending from the conductive surface. The element is operable to contact an adjacent surface abutting the flexible element and form a conductive connection with the adjacent surface. When assembled with other components in a housing, the electrically-conductive surface and the element may form a portion of a Faraday shield.

Important technical advantages of certain aspects of the present invention include shielding electrical components from electromagnetic radiation. Particular embodiments may include a row of flexible gaskets formed from electrically-conductive plastic molded into an electrically-conductive plastic base unit. The flexible gaskets enable the apparatus to make numerous contact points to an adjacent component or to ground. Particular embodiments enable gaskets to be formed from the same plastic as the base unit, thus reducing or eliminating the risk of an electrical short caused by a gasket detaching from the base unit. Particular embodiments may also reduce or eliminate the probability of gasket failure due to large temperature fluctuations and repetitive shear loads as the apparatus is inserted and removed from a housing. Other technical advantages of the present invention will be readily apparent to one skilled in the art from the following figures, description, and claims. Moreover, while specific advantages have been enumerated above, various embodiments may include all, some, or none of the enumerated advantages.

### BRIEF DESCRIPTION OF THE DRAWINGS

For a more complete understanding of the present invention and its advantage, reference is now made to the following descriptions, taken in conjunction with the accompanying drawings, in which:

FIG. 1 is a block diagram illustrating a system for shielding electrical components according to particular embodiments of the present invention;

FIG. 2 is a three-dimensional block diagram illustrating in more detail a particular embodiment of an electrically-conductive plastic base unit that may be utilized in the system of FIG. 1;

FIG. 3 is a block diagram illustrating a top view of the electrically-conductive plastic base unit of FIG. 2;

FIG. 4 is a block diagram illustrating a side view of the electrically-conductive plastic base unit of FIG. 2 contacting an adjacent component of the system of FIG. 1; and

FIG. 5 is a flow chart illustrating example operation of the system for shielding electrical components shown in FIG. 1.

### DETAILED DESCRIPTION OF THE INVENTION

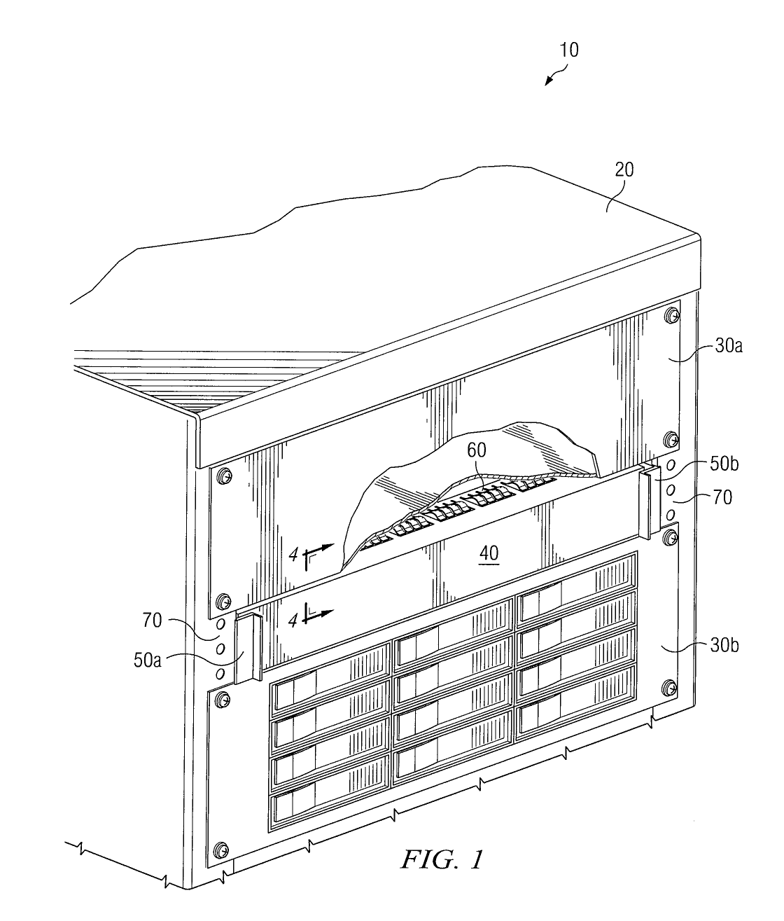

FIG. 1 illustrates a particular embodiment of a system 10 for using electrically-conductive plastic gaskets to contain electromagnetic radiation in an electrical chassis or cabinet. System 10 includes a housing 20, one or more components 30, a base unit 40, one or more latches 50, gaskets 60, and frame 70. To facilitate the containment of electromagnetic radiation radiated from certain elements of system 10 or the shielding of elements of system 10 from external electromagnetic radiation, gaskets 60, attached to or formed on one or more base units 40 mounted in housing 20, contact an adjacent surface of a neighboring component 30 or base unit 40, thereby creating an electrically-conductive path between the relevant base unit 40 and the adjacent surface. Because gaskets 60 are formed from electrically-conductive plastic, gaskets 60 may, in particular embodiments, be flexible. This flexibility may allow gaskets 60 to bridge gaps of various sizes between base units 30 and adjacent surfaces and may result in gaskets 60 being more resistant to wear than if formed from more rigid material.

Housing 20 encloses the various components of system 10 in part or in whole. In particular embodiments, housing 20, in conjunction with certain surfaces of components 30 and base unit 40, may form a Faraday cage or Faraday shield that shields components 30 and base unit 40 and/or other elements of system 10 from electromagnetic radiation. For the purposes of this description, housing 20 may “enclose” a particular component 30 or base unit 40 by forming a surface that entirely surrounds the relevant component 30 or base unit 40 or one that partially surrounds a portion of the relevant component 30 or base unit 40. As a result, in particular embodiments, components 30 and base unit 40 enclosed by housing 20 may have one or more of their surfaces exposed by housing 20. Housing 20 may be composed of a metal alloy, conductive plastic, or any other suitable material. Additionally, housing 20 may be shaped in any appropriate form or manner.

Components 30a and 30b (each of which may be referred to generically as “component 30” or collectively as “components 30”) are inserted into housing 20 and contact adjacent base unit 40 or another component 30. Components 30 may securely attach to frame 70 by mounting inside a groove, by attaching to a portion of frame 70 via latch 50, or by any other appropriate method. In particular embodiments of system 10 that do not include frame 70, components 30 may securely attach to housing 20. Although illustrated for purposes of example in FIG. 1 as mounted horizontally in housing 20, alternative embodiments of system 10 may include components 30 mounted vertically in housing 20. In general, however components 30 may be mounted in housing 20 by any appropriate method and in any appropriate orientation.

In particular embodiments, components 30 may represent computer hardware and/or software capable of performing computing functions. For example, component 30 may be a server, an Ethernet switch, a telecommunications switch, a router, a hub, a firewall, a proxy server, or a content filter. Component 30 may also be a spacer, panel, or other element that occupies space in housing 20 but performs no computing functions. In general, components 30 may be any suitable combination of hardware and/or software suitable to be inserted into housing 20 and to contact another component 30 or base unit 40.

Additionally, in particular embodiments, a particular component 30 may include certain features designed to form an electrically-conductive path between component 30 and another component 30 or base unit 40. In particular embodiments, components 30 may include a surface of electrically-conductive plastic that includes one or more gaskets 60. As a result, components 30 may provide electrical conductivity to an adjacent surface through electrically-conductive gasket 60. Although FIG. 1 illustrates for purposes of example two components 30 inserted in housing 20, alternative embodiments of system 10 may include any number and type of components 30.

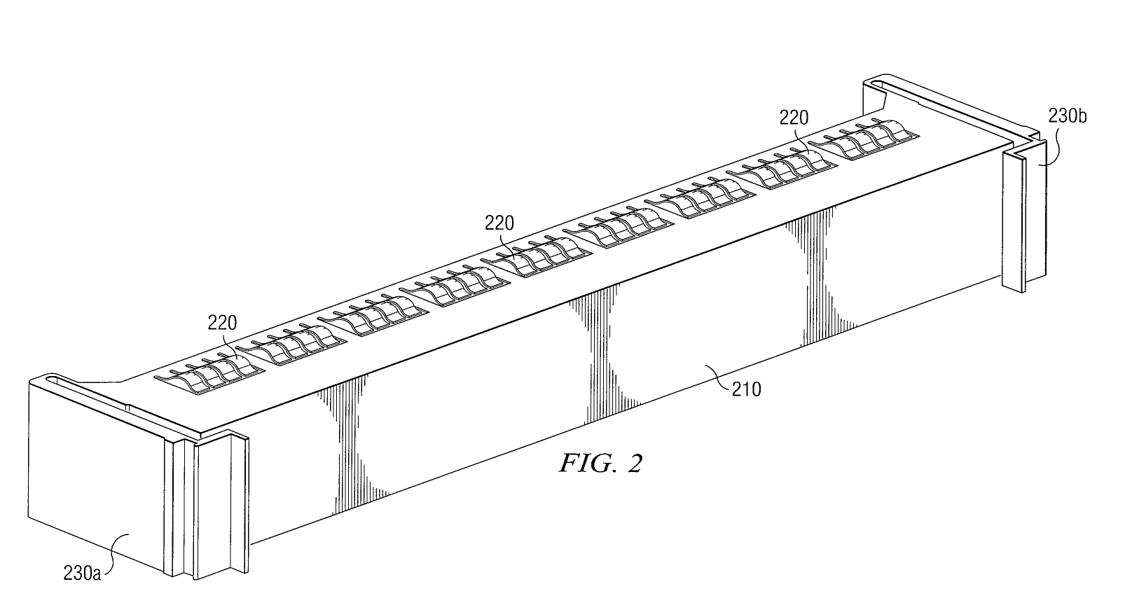

Base unit 40 is inserted into housing 20, attaches to frame 70, accommodates one or more gaskets 60, and contacts housing 20, component 30, another base unit 40, or any other appropriate element of system 10. As discussed further below with reference to FIG. 2, base unit 40 may be formed from a piece of electrically-conductive plastic. Although illustrated for purposes of example in FIG. 1 as inserted horizontally into housing 20, alternative embodiments of system 10 may include components 30 inserted vertically into housing 20. Additionally, although FIG. 1 illustrates for purposes of example a single base unit 40, alternative embodiments of system 10 may include any number and type of base units 40, arranged in any suitable order and manner in housing 20.

Latches 50a and 50b (each of which may be referred to generically as “latch 50” or collectively as “latches 50”) attach to base unit 40 and securely mount base unit 40 to housing 20 or frame 70. Latches 50 may represent any appropriate element for connecting base unit 40 to housing 20 or frame 70, including but not limited to screws, bolts, and pins. In particular embodiments, latches 50 may be flexible elements formed from electrically-conductive plastic and capable of grasping housing 20 or frame 70 when component 30 is inserted into housing 20. Furthermore, in particular embodiments, latches 50, base unit 40, and gasket 60 may be formed from a single piece of molded conductive plastic. In such embodiments, latches 50 and base unit 40 may represent different portions of a single conductive surface. Thus, an electrically-conductive path may be formed between base unit 40 and the adjacent surface through latches 50 and/or gasket 60, described below. In alternative embodiments, latches 50 may be formed from a separate piece of conductive plastic and attached to base unit 40. Although FIG. 1 depicts for purposes of example two latches 50 attached to base unit 40, alternative embodiments of system 10 may include any suitable number and types of latches 50.

Gaskets 60 are attached to or formed on base unit 40. When base unit 40 is inserted in housing 20, gaskets 60 may contact an adjacent surface of a neighboring component 30 base unit 40, of housing 20, or of other appropriate elements of system 10, and form an electrically-conductive path between the base unit 40 and the adjacent surface. In particular embodiments, this may allow base units 40, components 30, and housing 20 to form a Faraday cage around components 30 (or around portions of components 30) that contains electrical fields generated by components 30 and/or shields components 30 from external electrical fields. As discussed further below with reference to FIG. 2, gasket 60 may be formed from electrically-conductive plastic, molded into any appropriate shape. Gasket 60 may be configured to conduct electricity in several ways. For example, an electrically-conductive coating and/or paint may be applied to the surface of gasket 60. Conductive filler may be applied to a plastic molding material to provide conductivity to the molded plastic. Although FIG. 1 illustrates for purposes of example a row of gaskets 60 attached to an upper surface of base unit 40, alternative embodiments of system 10 may include any suitable number and arrangement of gaskets 60 on base unit 40.

Frame 70 secures components 30 and base unit 40 into housing 20. In particular embodiments frame 70 may be constructed of plastic, metal, or any other appropriate material suitable to accommodate components 30, base unit 40, or any other appropriate elements of system 10. In particular embodiments, system 10 may not include frame 70. In embodiments of system 10 that include frame 70, frame 70 may accommodate components 30 and base unit 40 by receiving one or more latch 50 or by any other appropriate method suitable to attach component 30 or base unit 40 to frame 70.

When assembled, components 30 are inserted into housing 20 and attached to frame 70 by latches 50 or secured in any other appropriate manner. In particular embodiments, a gap may be present in system 10 between or among various components 30 or between components 30 and housing 20. To fill in this gap, one or more base units 40 are inserted between different components 30 or between housing 20 and components 30. Base unit 40 may also be attached to frame 70 by latches 50, or secured in any other appropriate manner. A row of electrically-conductive plastic gaskets 60 may be flexibly attached to and arranged on base unit 40 to contact the adjacent surface of neighboring components 30 or base units 40 or of housing 20. Thus, in one embodiment, base unit 40, latches 50 and gasket 60 may collectively represent a filler panel. As a result, an electrical connection is created between base unit 40 and component 30. Similarly, component 30b may include gaskets 60 to provide electrical conductivity between component 30b and the adjacent surface of base unit 40. Additionally, one or more components 30 and base units 40 may be inserted into housing 20 until no electrical conductivity gaps are present between or among components 30, base unit 40, and housing 20. In this manner, a Faraday cage or Faraday shield is formed, shielding electrical components inside of housing 20 from external electromagnetic interference and/or shielding external electrical components from electromagnetic radiation generated by electrical components in system 10.

Because gaskets 60 are made of electrically-conductive rubber, in particular embodiments, gaskets 60 may be flexible and capable of bending to fit gaps of varying sizes. This may allow housing 20, components 30, and base units 40 to be manufactured with greater tolerance for variations in sizing or may allow housings 20, components 30, and base units 40 made by different manufacturers to be used together in system 10. Additionally, in particular embodiments, the flexibility of gaskets 60 may provide gaskets 60 with greater resistance to wear and deterioration resulting from gaskets 60 being deformed by insertion in or removal from housing 20. Furthermore, in particular embodiments, the body of base unit 40 and latches 50 may also be made from rubber, and as a result, base unit 40, latches 50, and gaskets 60 may all be formed from a single piece of electrically-conductive rubber, reducing the cost and complexity of manufacturing base unit 40. Thus, base unit 40 and gaskets 60 may provide numerous benefits. However, specific embodiments of base unit 40 and/or gaskets 60 may provide some, none, or all of these benefits.

FIG. 2 is a block diagram illustrating in greater detail a particular embodiment of base unit 40 shown in FIG. 1. As discussed above with reference to FIG. 1, base unit 40 is inserted into housing 20, accommodates one or more gaskets 60, and contacts another base unit 40, component 30, housing 20 or any other appropriate element of system 10. Collectively, base unit 40, latches 50 and gasket 60 may represent a filler panel. In particular embodiments, base unit 40 may be formed from an electrically-conductive plastic, molded into any appropriate shape suitable to occupy a space in housing 20. Although illustrated for purposes of example in FIG. 2 as having a particular shape, base unit 40 may, in alternative embodiments of system 10, have other appropriate shapes. As illustrated in FIG. 2, in particular embodiments, base unit 40, gaskets 60, and latches 50 may be formed from a single piece of electrically-conductive plastic. In alternative embodiments of system 10, base unit 40 may be formed from any appropriate combination of separately formed electrically-conductive plastic elements that are attached together. In general, the electrically-conductive plastic provides electrical conductivity between base unit 40, gaskets 60, and latches 50, such that electricity flowing to base unit 40 through any surface of base unit 40 is conducted through gaskets 60. Additionally, electricity flowing to base unit 40 through gaskets 60 is conducted to other surfaces of base unit 40.

Gasket 60 is attached to base unit 40, and is operable to conduct an electrical charge to an adjacent element of system 10. For example, gasket 60 may contact an adjacent component 30, as illustrated in a particular embodiment of system 10 in FIG. 1. In alternative embodiments of system 10, gasket 60 may contact another adjacent base unit 40, housing 20, or any other appropriate element of system 10. As discussed above with reference to FIG. 1, gasket 60 may be formed from electrically-conductive plastic which may conduct electricity on the surface of gasket 60. As noted above, gasket 60 may be configured to conduct electricity in several ways. For example, an electrically-conductive coating and/or paint may be applied to the surface of gasket 60. Conductive filler may be applied to a plastic molding material to provide conductivity to the molded plastic.

Gasket 60 may be flexibly or pliably attached to base unit 40, and thus resilient to an externally applied force. For example, gasket 60 may be formed from a pliable plastic, such that when an external force is applied to gasket 60, gasket 60 may bend at the point of attachment to base unit 40. Subsequently, when the mechanical force is removed, gasket 60 may return to its prior shape and position. The resilient force provided by the flexible or pliable plastic enables gasket 60 to depress when base unit 40 is inserted into housing 20 and to contact an adjacent component 30 or another adjacent base unit 40. As a result, gasket 60 may contact a relevant adjacent surface across gaps of varying sizes. Thus, system 10 provides for a high gap tolerance among elements of system 10.

In particular embodiments, gasket 60 may comprise a convex, rectangular surface protruding from base unit 40. In such embodiments, the convex surface of gasket 60 contacts the surface of an adjacent component 30 or adjacent base unit 40, thus providing an electrical conduit between base unit and the other relevant element of system 10. In alternative embodiments of system 10, gasket 40 may comprise a flat, rectangular surface protruding from base unit 40, in which the ends of the flat, rectangular surface of gasket 60 contact an adjacent component 30 or adjacent base unit 40. In other alternative embodiments of system 10, gasket 40 may include a domed surface protruding from base unit 40, where the distal surface of the dome contacts an adjacent component 30 or another base unit 40. In general however, gasket 60 may comprise any appropriate shape of any appropriate size suitable to perform the described functions.

Additionally, system 10 may include one or more gaskets 60. In embodiments that include multiple gaskets 60, gaskets 60 may be arranged in a sequence or row. In other embodiments, gaskets 60 may include differently sized and shaped gaskets 60, arranged without any particular pattern or order. In general, however, gaskets 60 may be attached to base unit 40 in any appropriate manner and arrangement suitable to perform the described functions.

Latches 50 attach to base unit 40 and securely attach base unit 40 to frame 70. As discussed above with reference FIG. 1, latches 50 may be formed from electrically-conductive plastic, which may conduct electricity on the surface of latches 50. In particular embodiments, latches 50, base unit 40, and gaskets 60 may be formed from a single piece of electrically-conductive plastic, molded into an appropriate shape suitable for inserting into housing 20. In alternative embodiments, latches 50 may be formed from a separate electrically-conductive plastic element and attached to base unit 40. Latch 50 may be flexibly or pliably attached to base unit 40, and thus resilient to an externally applied force. For example, latch 50 may be formed from a resilient plastic, such that when an external force is applied to latch 50, latch 50 may bend at the point of attachment to base unit 40. Subsequently, when the external force is removed, latch 50 may return to its prior shape and position. Thus, a user may insert base unit 40 into housing 20 by depressing inward latches 50, inserting base unit 40 into housing 20, and releasing latch 50. The resilient plastic of latches 50 thus provide an outward gripping force on frame 70, enabling base unit 40 to be securely mounted in housing 20. A user may remove base unit 40 from housing 20 by depressing inward latches 50 by a sufficient amount to clear frame 70, and by pulling base unit 40 toward the user. Although FIG. 2 illustrates for purposes of example two latches 50 attached to base unit 40, alternative embodiments of system 10 may include any number and type of latch 50.

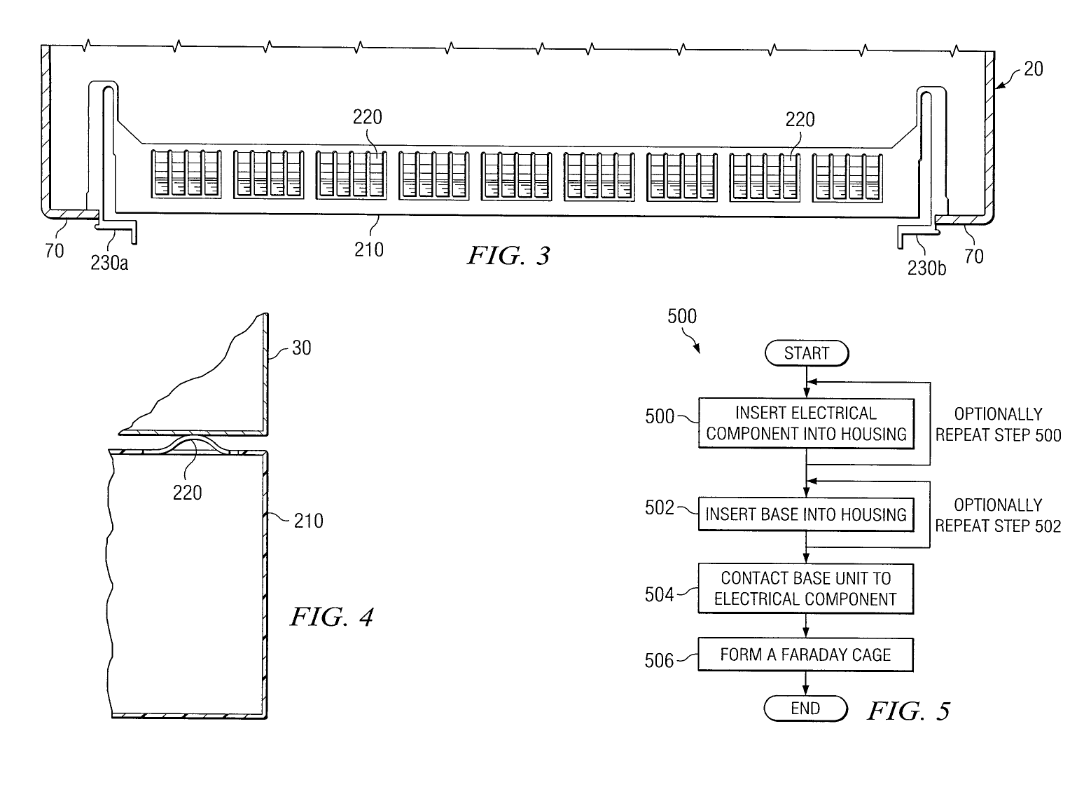

FIG. 3 is a block diagram illustrating a particular embodiment of base unit 40, with a view of the upper surface of a base unit 40 on which a row of gaskets 60 and latches 50 are flexibly attached. As shown, FIG. 3 illustrates the interior surface of base unit 310 on the upper portion of the figure, and the exterior surface of base unit 310 on the bottom portion of the figure.

FIG. 4 is a block diagram illustrating a portion of a particular embodiment of base unit 40 and component 30, with a view of a lateral surface of base unit 40 on which a row of gaskets 60 are flexibly attached to the upper surface of base unit 40. As shown, FIG. 4 illustrates a view of gasket 60 contacting the lower surface of an adjacent element of system 10. As discussed with reference to FIG. 2, gasket 60 is flexibly attached to base unit 40, and is thus able to contact the lower surface of an adjacent element of system 10 across gaps of varying sizes.

FIG. 5 is a flowchart illustrating operation of a particular embodiment of system 10 in shielding electrical components. The steps illustrated in FIG. 5 may be combined, modified, or deleted where appropriate, and additional steps may also be added to those shown. Additionally, the steps may be performed in any suitable order without departing from the scope of system 10.

Operation, in the illustrated example begins in step 500, with a user inserting component 30 into housing 20. As described above with respect to FIG. 1, component 30 may be a server, an Ethernet switch, a telecommunications switch, a router, a hub, a firewall, a proxy server, or a content filter. Component 30 may also be a spacer, panel, or other element that occupies space in housing 20 but performs no computing functions. Components 30 may be inserted into housing by securely attaching to frame 70 by mounting inside a groove, by attaching to a portion of frame 70 via latch 50, or by any other appropriate method. In particular embodiments of system 10 that do not include frame 70, components 30 may securely attach to housing 20. Additionally, housing 20 may comprise a plurality of slots, and step 500 may be optionally repeated until one or more of the slots in housing 20 is occupied by a particular component 30.

At step 502, base unit 40 is inserted into and attaches to housing 20. As discussed above with reference to FIG. 1, base unit 40 may be formed from an electrically-conductive plastic, molded into any appropriate shape suitable to occupy a space in housing 20. In particular embodiments, step 502 may be optionally repeated, resulting in multiple base units 40 inserted into housing 20. In particular embodiments, step 502 may be repeated until each empty slot in housing 20 is occupied by a particular base unit 40.

At step 504, base unit 40 contacts an adjacent base unit 40, component 30, housing 20 or any other appropriate element of system 10. In particular embodiments, a row of gaskets 60 on base unit 40 contacts an adjacent surface of component 30, housing 20, or an adjacent base unit 40. As described above with respect to FIG. 2, each of the gaskets 60 may comprise electrically-conductive plastic, operable to conduct electricity between base unit 40 and an adjacent element of system 10.

At step 506, a Faraday cage is formed among one or more components 30, base units 40, and housing 20. In particular embodiments of system 10, various elements of system 10 may each be electrically-conductive to an adjacent element, thereby forming a Faraday cage. Thus, in particular embodiments, external components external to system may be shielded from electrical radiation generated within system 10, and elements of system may be shielded from external electrical radiation.

Although the present invention has been described with several embodiments, numerous changes, variations, alterations, transformations, and modifications may be suggested to one skilled in the art, and it is intended that the present invention encompass such changes, variations, alterations, transformations, and modifications as fall within the scope of the appended claims.

What is claimed is:

1. An apparatus for shielding electromagnetic radiation comprising:
a conductive surface comprising electrically-conductive plastic;
a flexible element extending from the conductive surface, wherein the flexible element comprises electrically-conductive plastic, the flexible element operable to form a conductive connection between the conductive surface and an adjacent surface abutting the flexible element.

2. The apparatus of claim 1, wherein:
the flexible element comprises one of a plurality of flexible elements extending from the conductive surface;
each of the flexible elements comprises electrically-conductive plastic; and
each of the flexible elements is operable to form a conductive connection between the conductive surface and one or more adjacent surfaces abutting the flexible elements.

3. The apparatus of claim 2, wherein the plurality of flexible elements comprise a row of flexible elements extending from the conductive surface.

4. The apparatus of claim 1, wherein the flexible element is operable to form the conductive connection between the conductive surface and adjacent surface by forming the conductive connection across the surface of the flexible element.

5. The apparatus of claim 1, further comprising a plurality of latches operable to attach the conductive surface to a housing, wherein:
each of the plurality of latches comprise electrically-conductive plastic; and
each of the plurality of latches is operable to form a conductive connection between the conductive surface and an adjacent surface abutting one or more of the plurality of latches.

6. The apparatus of claim 5, wherein the latches comprise flexible latches operable to attach the conductive surface to a housing by grasping a portion of the housing.

7. The apparatus of claim 1, wherein the flexible element is operable to:
bend towards the conductive surface when a force is applied to the flexible element by the adjacent surface; and
return to an original position when the force is removed from the flexible element.

8. The apparatus of claim 1, wherein the flexible element and the conductive surface comprise a single piece of conductive plastic.

9. A system for shielding electromagnetic radiation comprising:
a conductive surface comprising electrically-conductive plastic;
a flexible element extending from the conductive surface, wherein the flexible element comprises electrically-conductive plastic, the flexible element operable to form a conductive connection between the conductive surface and an adjacent surface abutting the flexible element; and
a housing operable to:
receive the conductive surface; and
receive the adjacent surface.

10. The system of claim 9, wherein:
the flexible element comprises one of a plurality of flexible elements extending from the conductive surface;
each of the flexible elements comprises electrically-conductive plastic; and
each of the flexible elements are operable to form a conductive connection between the conductive surface and one or more adjacent surfaces abutting the flexible elements.

11. The system of claim 10, wherein the plurality of flexible elements comprises a row of flexible elements extending from the conductive surface.

12. The system of claim 9, wherein flexible element is operable to form the conductive connection between the conductive surface and adjacent surface by forming the conductive connection across the surface of the flexible element.

13. The system of claim 9, further comprising a plurality of latches operable to attach the conductive surface to the housing, wherein:
each of the plurality of latches comprise electrically-conductive plastic; and
each of the plurality of latches is operable to form a conductive connection between the conductive surface and an adjacent surface abutting one or more of the plurality of latches.

14. The system of claim 13, wherein the latches comprise flexible latches operable to attach the conductive surface to the housing by grasping a portion of the housing.

15. The system of claim 9, wherein the flexible element is operable to:
bend toward the conductive surface when a force is applied to the flexible element by the adjacent surface; and
return to an original position when the force is removed from the flexible element.

16. The system of claim 9, wherein the flexible element and the conducting surface comprise a single piece of conductive plastic.

17. A method for configuring a housing for electronic components, comprising:
inserting an electronic component into a housing; and
inserting a base unit into the housing, wherein the base unit comprises a conductive surface and a flexible element extending from the conductive surface, and wherein the flexible element comprises electrically-conductive plastic and is operable to form a conductive connection between the conductive surface and an adjacent surface of the electronic component abutting the flexible element.

18. The method of claim 17, wherein:
the housing comprises a plurality of slots;
inserting the electronic component comprises inserting one or more electronic components into the plurality of slots; and
inserting the base unit comprises inserting a base unit into each empty slot in the plurality of slots.

19. The method of claim 18, further comprising forming a Faraday cage around a portion of each electronic component inserted in the housing.

20. The method of claim 17, wherein:
the flexible element comprises a plurality of flexible elements extending from the conductive surface;
each of the flexible elements comprises electrically-conductive plastic; and
each of the flexible elements is operable to form a conductive connection between the conductive surface and one or more adjacent surfaces abutting the flexible elements.

21. The method of claim 20, wherein the plurality of flexible elements comprise a row of flexible elements extending from the conductive surface.

22. The method of claim 17, wherein inserting the base unit comprises inserting a single piece of conductive plastic that includes the flexible element and the conducting surface.

23. The method of claim 17, further comprising attaching the base unit to the housing with a plurality of latches, wherein:
each of the plurality of latches comprise electrically-conductive plastic; and
each of the plurality of latches is operable to form a conductive connection between the conductive surface and an adjacent surface abutting one or more of the plurality of latches.

24. The method of claim 17, wherein attaching the base unit to the housing comprises attaching the base unit to the housing with flexible latches that grasp a portion of the housing.

25. The method of claim 17, further comprising:
bending the flexible element towards the conductive surface with a force applied to the flexible element by the adjacent surface;
removing the base unit from the housing; and
returning the flexible element to an original position when the base unit is removed from housing.
